(19) United States
(12) Patent Application Publication
(10) Pub. No.: US 2024/0112988 A1
(43) Pub. Date: Apr. 4, 2024

(54) SEMICONDUCTOR DEVICE

(71) Applicant: ROHM CO., LTD., Kyoto-shi (JP)

(72) Inventors: Kaori UEBAYASHI, Kyoto-shi (JP); Maki MITA, Kyoto-shi (JP)

(21) Appl. No.: 18/538,483

(22) Filed: Dec. 13, 2023

Related U.S. Application Data
(63) Continuation of application No. PCT/JP2022/025550, filed on Jun. 27, 2022.

(30) Foreign Application Priority Data
Jun. 30, 2021 (JP) 2021-108426

(51) Int. Cl. H01L 23/495; H01L 23/00; H01L 25/065

(52) U.S. Cl. CPC H01L 23/4951; H01L 23/4952; H01L 23/49551; H01L 24/08; H01L 24/48; H01L 25/0652; H01L 2224/08145; H01L 2224/08155; H01L 2224/48227; H01L 2224/48247; H01L 2924/01029; H01L 2924/10253; H01L 2924/13091; H01L 2924/1711

(57) ABSTRACT

A semiconductor device includes a semiconductor element, a first lead electrically connected to the semiconductor element, and a connecting member connected to the semiconductor element and the first lead. The connecting member includes a core containing a first material, and a surface layer. The surface layer contains a first metal and covers the core. The first material includes an alloy in which at least a third metal is added to a second metal and has a higher corrosion resistance than the second metal. The third metal has the highest proportion among the metals added and has an atomic number greater than the second metal.

### TECHNICAL FIELD

The present disclosure relates to a semiconductor device.

### BACKGROUND ART

Various configurations have been proposed for semiconductor devices with semiconductor elements. In an example of a semiconductor device, a semiconductor element mounted on a die pad is connected to a lead with a wire, and these are covered with a sealing resin. JP-A-2021-27116, for example, discloses such a semiconductor device. The semiconductor device includes a semiconductor element, a first through a fifth leads, bonding wires, and a sealing resin. The semiconductor element is mounted on the obverse surface of a mount portion of the first lead. The electrodes of the semiconductor element and the second through the fifth leads are connected to each other with bonding wires. The sealing resin covers the semiconductor element, the bonding wires, and a part of each of the first through the fifth leads. The sealing resin is made of a black epoxy resin.

Generally, the sealing resin contains a sulfur component to improve adhesion to the leads. Meanwhile, Cu is used as the constituent material of the bonding wires. In this case, the bonding wires are likely to be corroded by the sulfur component and halogen contained in the sealing resin. Further, the surfaces of the bonding wires are likely to be oxidized, and the oxide films can inhibit bonding with the leads. A possible method for preventing these is to use a bonding wire in which a core made of Cu is covered with a coating such as Pd, for example. In such a bonding wire, the coating film protects the core made of Cu from the sulfur component and halogen in the sealing resin and also prevents the core from oxidizing.

### BRIEF DESCRIPTION OF THE DRAWINGS

FIG. 1 is a plan view of a semiconductor device according to a first embodiment of the present disclosure.

FIG. 2 is a plan view of the semiconductor device shown in FIG. 1, as seen through a resin member.

FIG. 3 is a front view of the semiconductor device shown in FIG. 1.

FIG. 4 is a front view of the semiconductor device shown in FIG. 1, as seen through a resin member.

FIG. 5 is a left side view of the semiconductor device shown in FIG. 1.

FIG. 6 is a sectional view taken along line VI-VI in FIG. 2.

FIG. 7 is an enlarged view of a part of FIG. 6.

FIG. 8 is an enlarged view of a part of FIG. 6.

FIG. 9 is a schematic sectional view of an electronic component according to the first embodiment.

FIG. 10 is a circuit diagram showing an example of the circuit configuration of the semiconductor device shown in FIG. 1.

FIG. 11 is a plan view of a semiconductor device according to a second embodiment of the present disclosure, as seen through a resin member.

FIG. 12 is a sectional view taken along line XII-XII in FIG. 11.

FIG. 13 is an enlarged view of a part of FIG. 12.

FIG. 14 is an enlarged view of a part of FIG. 12.

FIG. 15 is a plan view of a semiconductor device according to a third embodiment of the present disclosure, as seen through a resin member.

FIG. 16 is a plan view of a semiconductor device according to a fourth embodiment of the present disclosure, as seen through a resin member.

FIG. 17 is a plan view of a semiconductor device according to a fifth embodiment of the present disclosure, as seen through a resin member.

### DETAILED DESCRIPTION OF EMBODIMENTS

The following describes preferred embodiments of the present disclosure in detail with reference to the drawings.

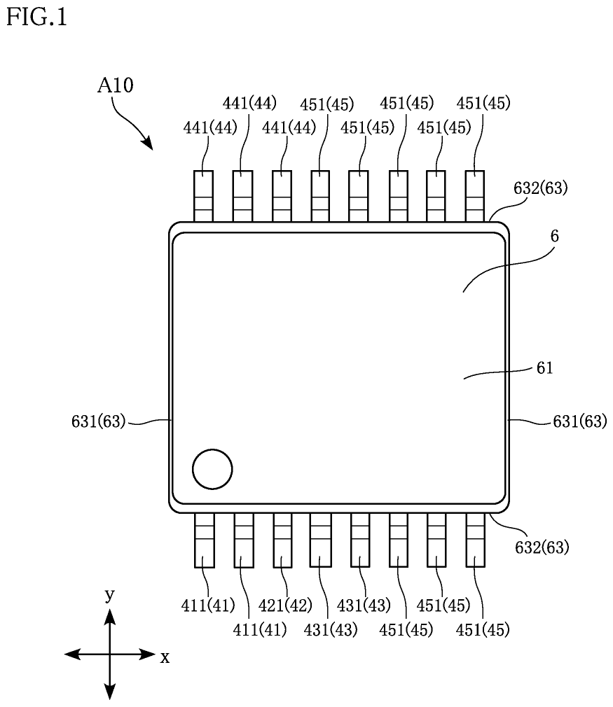

A semiconductor device A10 according to a first embodiment of the present disclosure will be described based on FIGS. 1 to 9. The semiconductor device A10 is to be surface-mounted on a circuit board of a variety of equipment. The semiconductor device A10 may have a package called SOP (Small Outline Package), for example. The package type of the semiconductor device A10 is not limited. The semiconductor device A10 is, for example, a power supply IC. The use and function of the semiconductor device A10 are not limited. The semiconductor device A10 is rectangular (or generally rectangular) as viewed in the thickness direction. The dimensions of the semiconductor device A10 are not particularly limited. The semiconductor device A10 includes an electronic component 1, a conductive support member 4, connecting members 5, and a resin member 6.

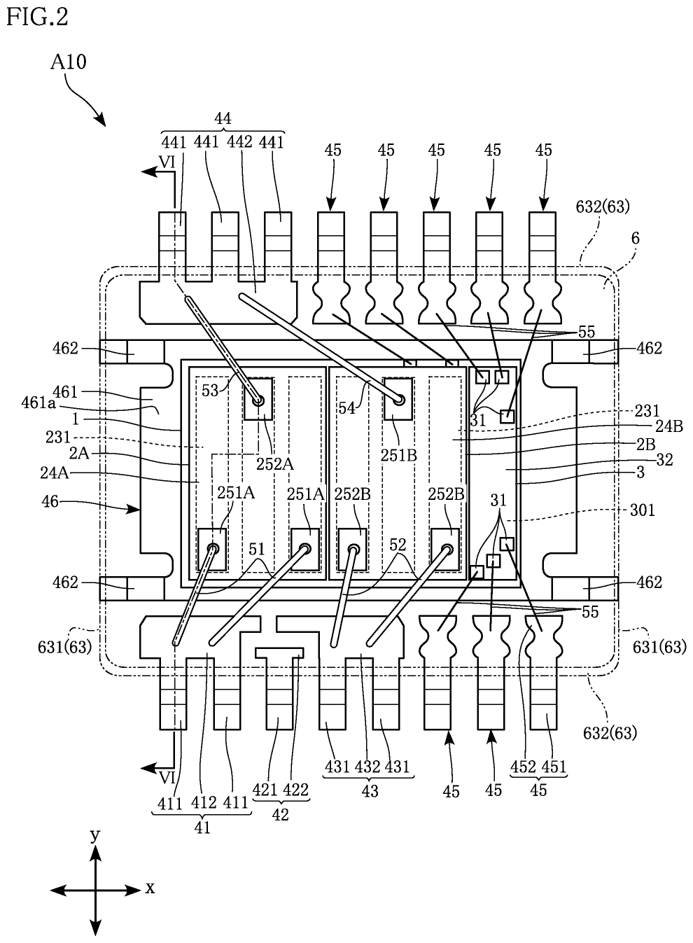

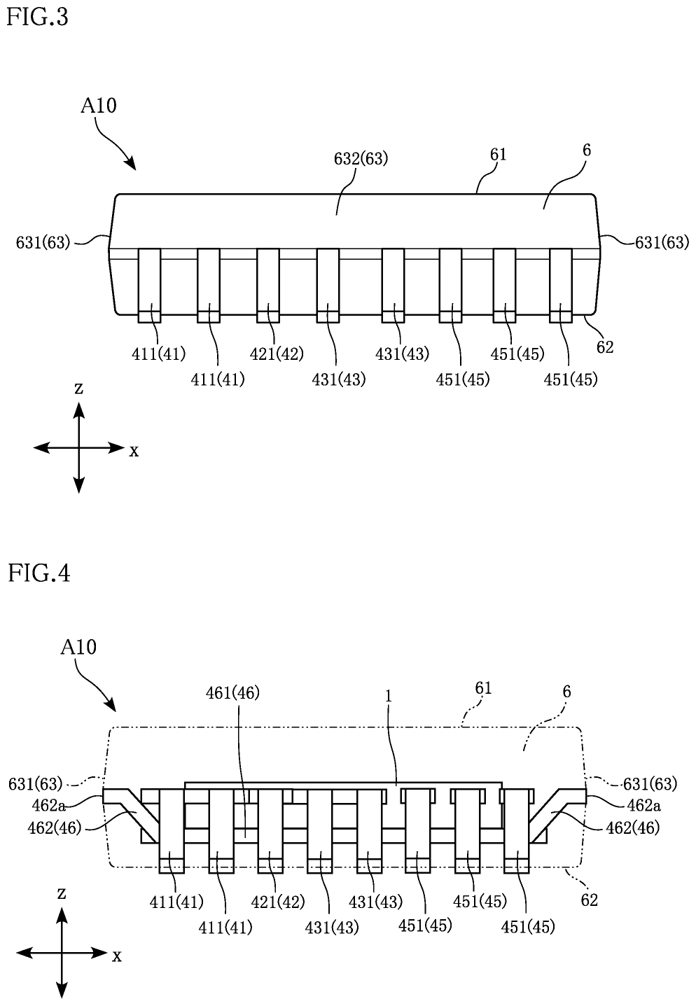

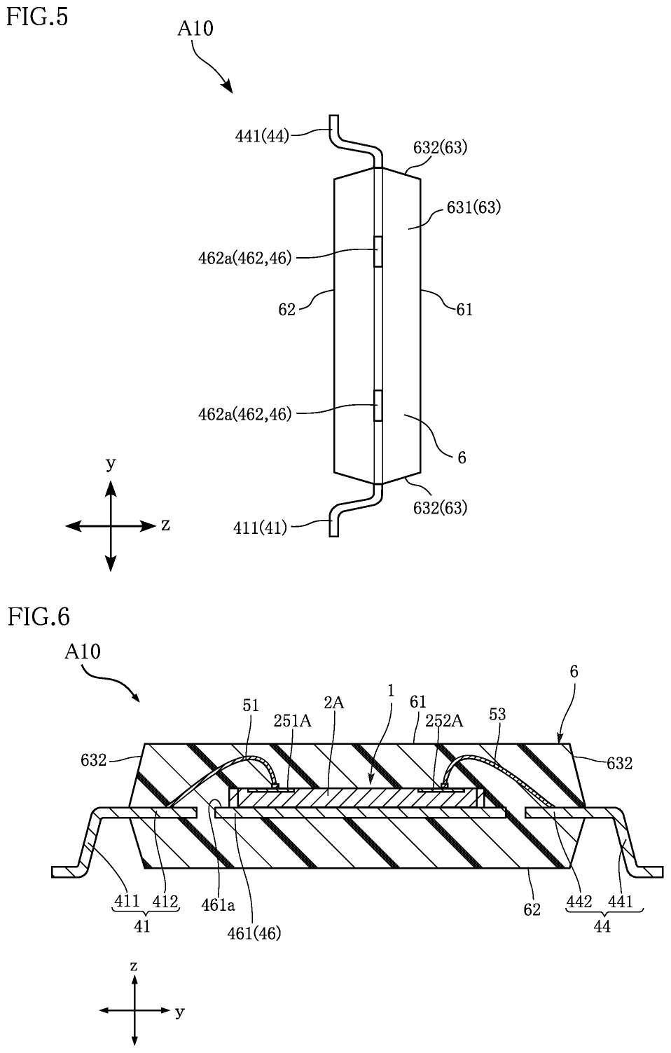

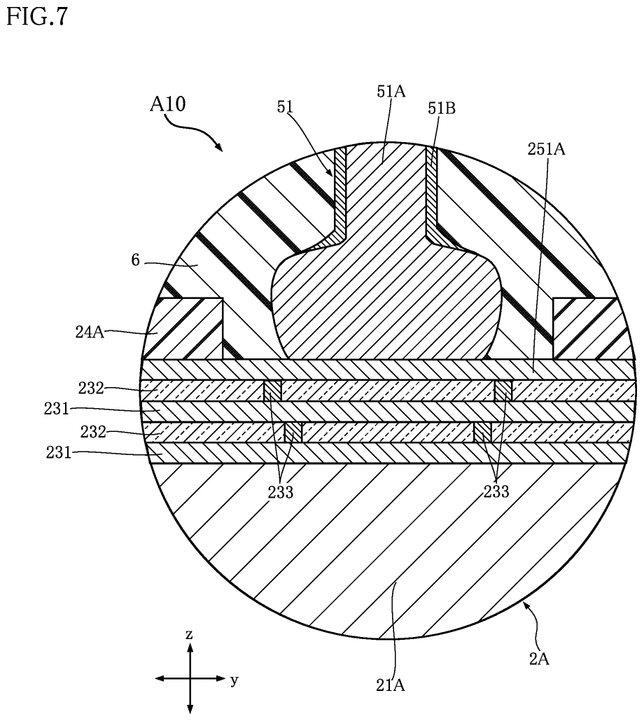

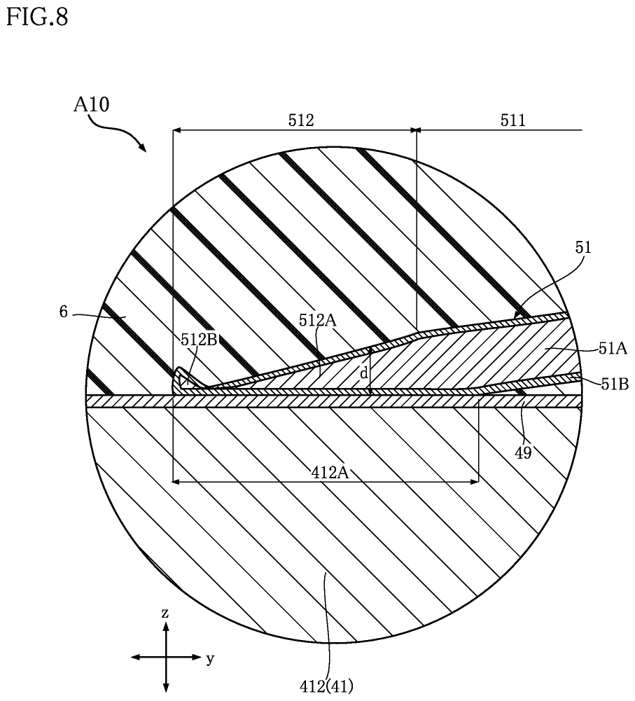

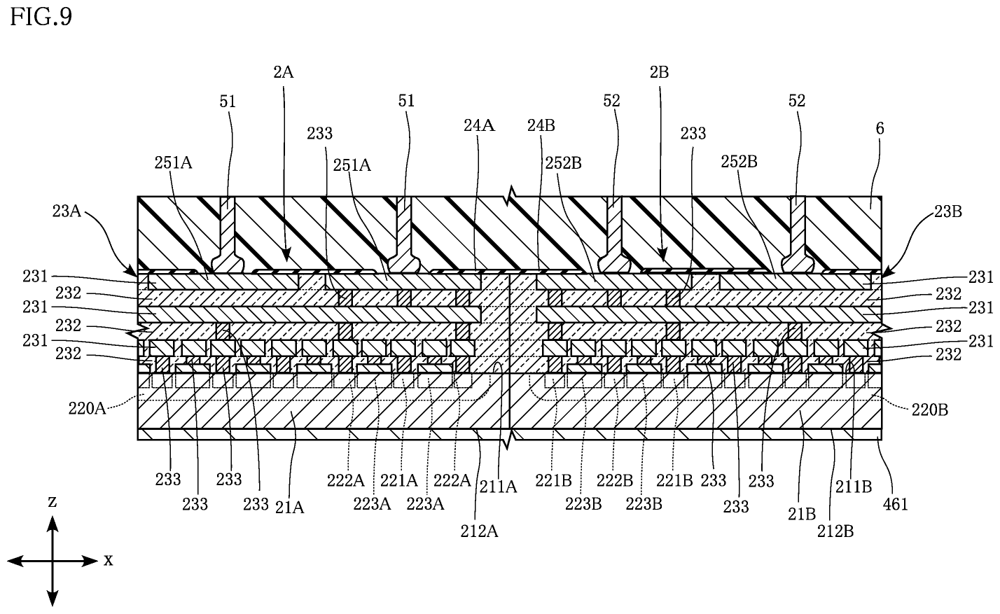

FIG. 1 is a plan view of the semiconductor device A10. FIG. 2 is a plan view of the semiconductor device A10. For the convenience of understanding, FIG. 2 shows the resin member 6 as transparent and indicates the outlines of the resin member 6 by imaginary lines (double dashed lines). FIG. 3 is a front view of the semiconductor device A10. FIG. 4 is a front view of the semiconductor device A10. For the convenience of understanding, FIG. 4 shows the resin member 6 as transparent and indicates the outlines of the resin member 6 by imaginary lines (double dashed lines). Note that the connecting members 5 are omitted in FIG. 4. FIG. 5 is a left side view of the semiconductor device A10. FIG. 6 is a sectional view taken along line VI-VI in FIG. 2. FIG. 7 is an enlarged view of a part of FIG. 6. FIG. 8 is an enlarged view of a part of FIG. 6. FIG. 9 is a schematic sectional view of the electronic component 1 (first semiconductor elements 2A and 2B, described later).

For the convenience of description, the thickness direction of the semiconductor device A10 is defined as a z direction, the direction (the horizontal direction in FIGS. 1 and 2) along one side of the semiconductor device A10 that is orthogonal to the z direction is defined as an x direction, and the direction (the vertical direction in FIGS. 1 and 2) orthogonal to the z direction and the x direction is defined as a y direction. In the description given below, one side in the z direction (the top side in the front view shown in FIG. 3) may be referred to as “upward” or “upper”, while the other side in the z direction (the bottom side in the front view shown in FIG. 3) may be referred to as “downward” or “lower”. However, such description does not limit the posture or orientation of the semiconductor device A10.

The electronic component 1 serves as a functional core of the semiconductor device A10. The electronic component 1 is bonded to the conductive support member 4 (the die pad 46, described later) with a bonding material, not shown. The electronic component 1 includes two first semiconductor elements 2A and 2B, and a second semiconductor element 3.

Each of the first semiconductor elements 2A and 2B is, for example, a MOSFET (Metal Oxide Semiconductor Field Effect Transistor). Each of the first semiconductor elements 2A and 2B is not limited to a MOSFET, and may be other transistors such as a bipolar transistor or an IGBT (Insulated Gate Bipolar Transistor) or may be a diode, for example.

As shown in FIGS. 2 and 9, the first semiconductor element 2A includes a semiconductor substrate 21A, a wiring layer 23A, a protective film 24A, and a plurality of electrode pads 251A and 252A (not shown in FIG. 9).

The semiconductor substrate 21A is made of a semiconductor material such as Si (silicon), SiC (silicon carbide) and Ca₂O₃ (gallium oxide). The semiconductor substrate 21A has a substrate obverse surface 211A and a substrate reverse surface 212A as shown in FIG. 9. The substrate obverse surface 211A and the substrate reverse surface 212A are spaced apart from each other in the z direction. The substrate obverse surface 211A faces upward. The substrate reverse surface 212A faces downward.

As shown in FIG. 9, the semiconductor substrate 21A has an active region 220A formed on the substrate obverse surface 211A side. The active region 220A includes semiconductor regions 221A, 222A, and 223A. The semiconductor region 221A is, for example, a drain region. The semiconductor region 222A is, for example, a source region. The semiconductor region 223A is, for example, a gate region.

As shown in FIG. 9, the wiring layer 23A is formed on the substrate obverse surface 211A of the semiconductor substrate 21A. The wiring layer 23A is made up of a plurality of conductive layers 231 and a plurality of insulating layers 232 that are alternately laminated. The conductive layers 231 are electrically connected to each other through vias 233 formed to penetrate the insulating layers 232. The configuration shown in FIG. 9 is one example, and the wiring layer 23A is not limited to this.

As shown in FIG. 9, the protective film 24A is formed on the wiring layer 23A and covers the upper surface of the wiring layer 23A. As shown in FIG. 2, the protective film 24A has openings, and the electrode pads 251A and 252A are exposed through the openings. The protective film 24A is, for example, a Si₃N₄ layer or a SiO₂ layer formed by plasma CVD, or a polyimide resin layer formed by coating. The protective film 24A may be formed by a combination of these.

Each of the electrode pads 251A and 252A is a terminal of the first semiconductor element 2A. Each of the electrode pads 251A is electrically connected to the semiconductor region 221A via the wiring layer 23A. Thus, each electrode pad 251A is a drain terminal of the first semiconductor element 2A. One of the connecting members 5 (a wire 51 described later) is bonded to each electrode pad 251A. The electrode pad 252A is electrically connected to the semiconductor region 222A via the wiring layer 23A. Thus, the electrode pad 252A is a source terminal of the first semiconductor element 2A. One of the connecting members 5 (a wire 53 described later) is bonded to the electrode pad 252A.

As shown in FIGS. 2 and 9, the first semiconductor element 2B includes a semiconductor substrate 21B, a wiring layer 23B, a protective film 24B, and a plurality of electrode pads 251B (not shown in FIG. 9) and 252B.

The semiconductor substrate 21B is made of a semiconductor material such as Si (silicon), SiC (silicon carbide) and Ca₂O₃ (gallium oxide). The semiconductor substrate 21B has a substrate obverse surface 211B and a substrate reverse surface 212B as shown in FIG. 9. The substrate obverse surface 211B and the substrate reverse surface 212B are spaced apart from each other in the z direction. The substrate obverse surface 211B faces upward. The substrate reverse surface 212B faces downward.

As shown in FIG. 9, the semiconductor substrate 21B has an active region 220B formed on the substrate obverse surface 211B side. The active region 220B includes semiconductor regions 221B, 222B, and 223B. The semiconductor region 221B is, for example, a drain region. The semiconductor region 222B is, for example, a source region. The semiconductor region 223B is, for example, a gate region.

As shown in FIG. 9, the wiring layer 23B is formed on the substrate obverse surface 211B of the semiconductor substrate 21B. The wiring layer 23B is configured in the same manner as the wiring layer 23A. That is, the wiring layer 23B is made up of a plurality of conductive layers 231 and a plurality of insulating layers 232 that are alternately laminated. The conductive layers 231 are electrically connected to each other through vias 233 formed to penetrate the insulating layers 232. The configuration shown in FIG. 9 is one example, and the wiring layer 23B is not limited to this.

As shown in FIG. 9, the protective film 24B is formed on the wiring layer 23B and covers the upper surface of the wiring layer 23B. As shown in FIG. 2, the protective film 24B has openings, and the electrode pads 251B and 252B are exposed through the openings. The protective film 24B is, for example, a Si₃N₄ layer or a SiO₂ layer formed by plasma CVD, or a polyimide resin layer formed by coating. The protective film 24B may be formed by a combination of these. The protective film 24A and the protective film 24B may be integrally formed.

Each of the electrode pads 251B and 252B is a terminal of the first semiconductor element 2B. The electrode pad 251B is electrically connected to the semiconductor region 221B via the wiring layer 23B. Thus, each electrode pad 251B is a drain terminal of the first semiconductor element 2B. One of the connecting members 5 (a wire 54 described later) is bonded to the electrode pad 251B. Each of the electrode pads 252B is electrically connected to the semiconductor region 222B via the wiring layer 23B. Thus, the electrode pad 252B is a source terminal of the first semiconductor element 2B. One of the connecting members 5 (a wire 52 described later) is bonded to each electrode pad 252B.

The second semiconductor element 3 is, for example, a driver IC. The second semiconductor element 3 drives and controls the first semiconductor elements 2A and 2B. The second semiconductor element 3 is electrically connected to each of the first semiconductor elements 2A and 2B. In one example, the second semiconductor element 3 is electrically connected to the semiconductor region 223A (the gate region) of the first semiconductor element 2A and outputs a control signal to the semiconductor region 223A (the gate region) to control the first semiconductor element 2A. Similarly, the second semiconductor element 3 is electrically connected to the semiconductor region 223B (the gate region) of the first semiconductor element 2B and outputs a control signal to the semiconductor region 223B (the gate region) to control the first semiconductor element 2B.

The second semiconductor element 3 has an element obverse surface 301 facing upward. The element obverse surface 301 is covered with a protective film 32 similar to the protective films 24A and 24B. The protective film 32 has openings, through which electrode pads 31 are exposed. In the present embodiment, the second semiconductor element 3 is formed with a plurality of electrode pads 31. A respective one of the connecting members 5 (the wires 55 described later) is bonded to each electrode pad 31.

When the semiconductor device A10 is mounted on a circuit board of an electronic device or the like, the conductive support member 4 forms a conductive path between the electronic component 1 and the circuit board. The conductive support member 4 supports the electronic component 1. The constituent material of the conductive support member 4 is, for example, Cu (copper) or a copper alloy. The constituent material of the conductive support member 4 is not limited. The conductive support member 4 is made of a lead frame formed by stamping or etching a metal plate. The thickness of the conductive support member 4 is, for example, about 0.2 mm. As shown in FIG. 2, the conductive support member 4 includes a lead 41, a lead 42, a lead 43, a lead 44, a plurality of leads 45, and a die pad 46. The lead 41, the lead 42, the lead 43, the lead 44, the leads 45 and the die pad 46 are spaced apart from each other.

As shown in FIG. 2, the lead 41 includes two terminal portions 411 and a pad portion 412. The pad portion 412 has a rectangular shape elongated in the x direction in plan view, with a notch at a corner on the side closer to the lead 42 (the lower right corner in FIG. 2). The notch is formed to avoid contact with the lead 42. When the pad portion is configured to avoid contact with the lead 42, the notch need not be provided. Wires 51 are bonded to the pad portion 412. The pad portion 412 has a metal layer 49 as shown in FIG. 8. The metal layer 49 is located on the upper side (the side on which wires 51 are bonded) of the pad portion 412. The metal layer 49 is in contact with the resin member 6. The metal layer 49 contains, for example, Ag and may be formed by plating.

Each terminal portion 411 is partially exposed from the resin member 6. Each terminal portion 411 is connected to the pad portion 412 at the portion covered with the resin member 6. Each terminal portion 411 is bent in the z direction at the portion exposed from the resin member 6. The surface of each terminal portion 411 may be plated with Sn, for example.

As shown in FIG. 2, the lead 42 includes a terminal portion 421 and a pad portion 422. The pad portion 422 has a rectangular shape elongated in the x direction in plan view. In plan view, the pad portion 422 is larger than the terminal portion 421 in dimension in the x direction. The pad portion 422 is covered with the resin member 6. None of the connecting members 5 is connected to the pad portion 422. The pad portion 422 is electrically insulated from the electronic component 1. The terminal portion 421 is partially exposed from the resin member 6. The terminal portion 421 is connected to the pad portion 422 at the portion covered with the resin member 6. The terminal portion 421 is bent in the z direction at the portion exposed from the resin member 6. The surface of the terminal portion 421 may be plated with Sn, for example.

As shown in FIG. 2, the lead 43 includes two terminal portions 431 and a pad portion 432. The pad portion 432 has a rectangular shape elongated in the x direction in plan view, with a notch at a corner on the side closer to the lead 42 (the lower left corner in FIG. 2). The notch is formed to avoid contact with the lead 42. When the pad portion is configured to avoid contact with the lead 42, the notch need not be provided. Wires 52 are bonded to the pad portion 432. The pad portion 432 has a metal layer 49. The metal layer 49 is located on the upper side (the side on which wires 52 are bonded) of the pad portion 432.

Each terminal portion 431 is partially exposed from the resin member 6. Each terminal portion 431 is connected to the pad portion 432 at the portion covered with the resin member 6. Each terminal portion 431 is bent in the z direction at the portion exposed from the resin member 6. The surface of each terminal portion 431 may be plated with Sn, for example.

As shown in FIG. 2, the lead 44 includes three terminal portions 441 and a pad portion 442. The pad portion 442 has a rectangular shape elongated in the x direction in plan view. A wire 53 and a wire 54 are bonded to the pad portion 442. The pad portion 442 has a metal layer 49. The metal layer 49 is located on the upper side (the side on which wires 53 and 54 are bonded) of the pad portion 432.

Each terminal portion 441 is partially exposed from the resin member 6. Each terminal portion 441 is connected to the pad portion 442 at the portion covered with the resin member 6. Each terminal portion 441 is bent in the z direction at the portion exposed from the resin member 6. The surface of each terminal portion 441 may be plated with Sn, for example.

As shown in FIG. 2, each of the lead 45 includes a terminal portion 451 and a pad portion 452. The pad portion 452 is constricted in the middle in the y direction in plan view. A wire 55, described later, is bonded to the pad portion 452. The pad portion 452 has a metal layer 49. The metal layer 49 is located on the upper side (the side on which a wire 55 is bonded) of the pad portion 452.

The terminal portion 451 is partially exposed from the resin member 6. The terminal portion 451 is connected to the pad portion 452 at the portion covered with the resin member 6. Each terminal portion 451 is bent in the z direction at the portion exposed from the resin member 6. The surface of the terminal portion 451 may be plated with Sn, for example.

The die pad 46 carries the electronic component 1. The die pad 46 is not electrically connected to the electronic component 1 in the present embodiment, but may be configured to be electrically connected to the electronic component 1. As shown in FIG. 2, the die pad 46 includes a pad portion 461 and a plurality of extension portions 462.

As shown in FIG. 2, the pad portion 461 has a die pad obverse surface 461a facing upward. The electronic component 1 is bonded to the center of the die pad obverse surface 461a.

Each of the extension portions 462 extends from the pad portion 461. Each extension portion 462 has an end surface 462a exposed from the resin member 6. The reverse surface of the pad portion 461, which faces downward, is covered with the resin member 6 in the present embodiment, but the reverse surface may be exposed from the resin member 6.

As shown in FIG. 2, the lead 41, the lead 42, the lead 43 and some of the leads 45 of the conductive support member 4 are disposed on one side in the y direction of the die pad 46 in plan view. These terminals 411, 421, 431 and 451 overlap with each other as viewed in the x direction. The lead 44 and the remaining leads 45 are disposed on the other side in the y direction of the die pad 46 in plan view. These terminals 441 and 451 overlap with each other as viewed in the x direction. As shown in FIG. 2, the terminal portions 411 of the lead 41, the terminal portion 421 of the lead 42, and the terminal portions 431 of the lead 43 are arranged side by side in the x direction in plan view. In plan view, the terminal portion 421 of the lead 42 is flanked by the terminal portions 411 of the lead 41 and the terminal portions 431 of the lead 43.

Each of the connecting members 5 electrically connects separated members to each other. Each connecting member 5 electrically connects the electronic component 1 (one of the first semiconductor elements 2A,2B or the second semiconductor element 3) and one of the components of the conductive support member 4. The connecting members 5 may include one used for electrical connection within the electronic component 1 (e.g., electrical connection between the first semiconductor elements 2A and 2B and the second semiconductor element 3). Each connecting member 5 is a linear member having a circular cross section. Each connecting member 5 is a so-called bonding wire. As shown in FIG. 2, the connecting members 5 include two wires 51, two wires 52, a wire 53, a wire 54, and a plurality of wires 55.

Each of the two wires 51 electrically connects one of the electrode pads 251A of the first semiconductor element 2A and the pad portion 412 of the lead 41 to each other. As shown in FIG. 2, each wire 51 is bonded to one of the electrode pads 251A at one end and bonded to the pad portion 412 at the other end. The thickness (wire diameter) of each wire 51 is not limited, but may be about 15 μm or more and 50 μm or less. As shown in FIGS. 7 and 8, each wire 51 includes a core 51A and a surface layer 51B covering the core.

The constituent material of the core 51A is an alloy in which Pt as an additive metal is added to Cu, which is the primary or base metal component. This alloy, in which Pt is added to Cu to improve corrosion resistance to sulfur, has a higher corrosion resistance to sulfur than that of Cu. The alloy may contain other additive metals in addition to Pt. Pt has the highest proportion among the additive metals in the alloy, and its content is, without limitation, about 50 ppm or more and 300 ppm or less by mass. The additive metal for improving corrosion resistance to sulfur is not limited to Pt and may be other metals, and preferably, is a metal with an atomic number greater than that of Cu. The base metal component of the constituent material of the core 51A is not limited to Cu and may be other metals. In such a case as well, the constituent material of the core 51A is an alloy in which an additive metal for improving the corrosion resistance to sulfur is added to the base metal component. The thickness of the core 51A is not limited, but may be about 0.03 μm or more and 0.30 μm or less.

The constituent material of the surface layer 51B contains, for example, Pd. The surface layer 51B is provided to protect the core 51A from corrosion by sulfur and halogen and prevent oxidation of the core 51A. As shown in FIG. 8, the surface layer 51B is in contact with the metal layer 49 of the pad portion 412 of the lead 41. The constituent material Pb of the surface layer 51B has a larger contact area with the metal layer 49 of the pad portion 412 than the constituent material of the surface layer 51B (an alloy in which Pt is added to Cu), thereby resulting in a greater bonding strength to the lead 41. That is, the surface layer 51B also functions to increase the bonding strength between the wire 51 and the lead 41. The constituent material of the surface layer 51B is not limited to Pd, and may be any metal having the above-described functions.

As shown in FIG. 8, each wire 51 has a main portion 511 and an end portion 512. The end portion 512 is interposed between the main portion 511 and the pad portion 412 of the lead 41. The end portion 512 has a tapered section 512A and a tip 512B. The tapered section 512A is connected to the main portion 511 and its dimension d in the z direction decreases as proceeding away from the main portion 511. The bond interface 412A between the pad portion 412 and the wire 51 extends over the main portion 511 and the end portion 512. The tip 512B is connected to the tapered section 512A and protrudes from the tapered section 512A in the z direction.

Each wire 51 is formed by wire bonding. The wire bonding uses a wire, which is prepared by forming a coating film to become the surface layer 51B on a wire material as the core 51A. The method for forming a coating film on the surface of the wire material is not particularly limited, and may be plating, vapor deposition, or melting, for example. The formation of the wire 51 may be performed as follows. First, first bonding is performed by melting the tip of a wire to form a ball and then pressing the ball against an electrode pad 251A of the first semiconductor element 2A. The surface layer 51B melts into the core 51A in forming the ball, and therefore, the surface layer 51B does not cover the core 51A at the portion of the wire 51 that is bonded to the electrode pad 251A, as shown in FIG. 7. However, depending on the discharge condition or the type of the wire material, the surface layer 51B may cover a part or the entirety of the core 51A at the bond portion. In such a case, the thickness (dimension in the z direction) of the bond portion becomes smaller. Next, second bonding is performed by feeding the wire material and pressing it against the pad portion 412 of the lead 41. The second bonding forms the end portion 512.

Each of the two wires 52 electrically connects one of the electrode pads 252B of the first semiconductor element 2B and the pad portion 432 of the lead 43 to each other. As shown in FIG. 2, each wire 52 is bonded to one of the electrode pads 252B at one end and bonded to the pad portion 432 at the other end. The wire 53 electrically connects the electrode pad 252A of the first semiconductor element 2A and the pad portion 442 of the lead 44 to each other. As shown in FIG. 2, the wire 53 is bonded to the electrode pad 252A at one end and bonded to the pad portion 442 at the other end. The wire 54 electrically connects the electrode pad 251B of the first semiconductor element 2B and the pad portion 442 of the lead 44 to each other. As shown in FIG. 2, the wire 54 is bonded to the electrode pad 251B at one end and bonded to the pad portion 442 at the other end. The configuration of the wires 52 to 54 are the same as that of the wire 51.

Each of the wires 55 electrically connects one of the electrode pads 31 of the second semiconductor element 3 and the pad portion 452 of one of the leads 45 to each other. As shown in FIG. 2, each wire 55 is bonded to one of the electrode pads 31 at one end and bonded to the pad portion 452 of one of the leads 45 at the other end. Each wire 55 does not include a portion corresponding to the surface layer 51B of the wires 51 and consists solely of a portion corresponding to the core 51A. The constituent material of the wires 55 is Cu, to which no other metals are added. The constituent material of the wires 55 is not limited. For example, the constituent material of the wires 55 may be a metal (e.g., Au) with a higher electrical resistivity than Cu, which is the base metal component of the core 51A of the wires 51. The thickness (wire diameter) of each wire 55 is not limited, but may be about 15 μm or more and 50 μm or less, for example.

Each of the wires 51 to 54 is bonded to one of the drain terminals (the electrode pads 251A and 251B) and source terminals (electrode pads 252A and 252B) of the first semiconductor elements 2A and 2B. Since a relatively large current flows in the drain terminals and source terminals, a relatively large current flows in the wires 51 to 54 as well. Each wire 55 is bonded to one of the electrode pads 31 of the second semiconductor element 3. The current flowing in each electrode pad 31 is relatively small as compared with the current flowing in a drain terminal and a source terminal. Therefore, the current flowing in each wire 55 is smaller than the current flowing in each of the wires 51 to 54. Generally, as the current flowing in a wire increases, corrosion of the wire by sulfur is more likely to be promoted. In the semiconductor device A10, therefore, only the wires 51 to 54, in which a large current flows and corrosion by sulfur is more likely to be promoted, have the configuration in which the core 51A is covered with the surface layer 51B. The wires 55, in which a relatively small current flows, do not include the surface layer.

The resin member 6 covers the electronic component 1, a part of the conductive support member 4, and the connecting members 5. The resin member 6 is made of an insulating resin material. The constituent material of the resin member 6 is, for example, black epoxy resin. The material and color of the resin member 6 are not limited. The resin member 6 contains a sulfur component to improve adhesion to the conductive support member 4. The sulfur content in the resin member 6 is 5 ppm or more and 30 ppm or less by mass. The sulfur content described above can be measured, for example, by the following method. The resin composition of the resin member 6 is thermally cured at 175° C. for 4 hours to obtain a cured material, and the cured material is crushed to obtain a crushed material. Next, the gas produced by heat-treating the crushed material at 150° C. for 8 hours is collected by an aqueous solution of hydrogen peroxide. Next, the sulfur content in the total amount of the resin composition is calculated from the amount of sulfate ions in the aqueous solution of hydrogen peroxide.

The resin member 6 is, for example, rectangular in plan view. The resin member 6 is formed by transfer molding using a mold, for example. The constituent material, shape, and forming method of the resin member 6 are not limited. The resin member 6 has a resin obverse surface 61, a resin reverse surface 62, and a plurality of resin side surfaces 63.

The resin obverse surface 61 and the resin reverse surface 62 are spaced apart from each other in the z direction. The resin obverse surface 61 is the upper surface of the resin member 6. The resin reverse surface 62 is the lower surface of the resin member 6. The resin side surfaces 63 are connected to both the resin obverse surface 61 and the resin reverse surface 62 and sandwiched between these surfaces in the z direction. The resin member 6 includes a pair of resin side surfaces 631 spaced apart from each other in the x direction and a pair of resin side surfaces 632 spaced apart from each other in the y direction. Each of the leads 41 to protrudes from either one of the resin side surfaces 632.

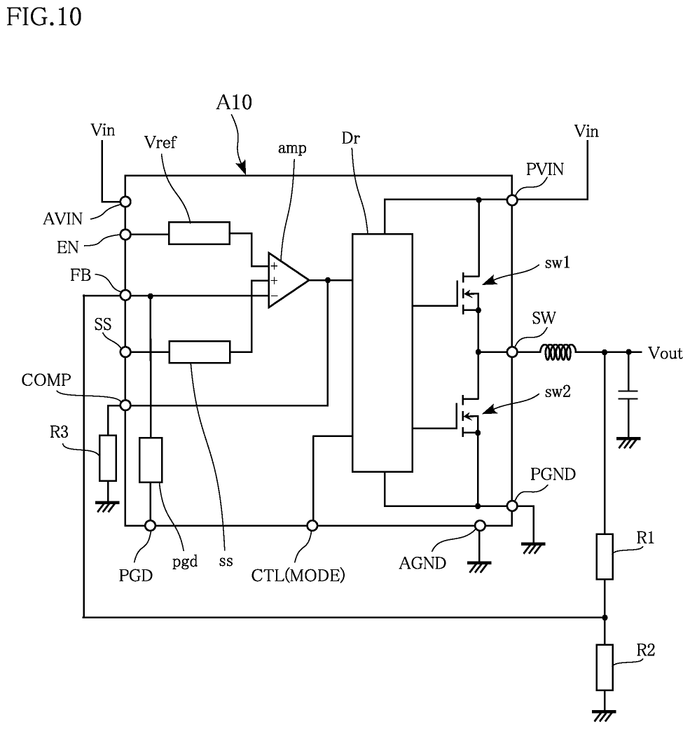

FIG. 10 is a circuit diagram showing an example of the circuit configuration of the semiconductor device A10. Specifically, FIG. 10 is a circuit diagram when the semiconductor device A10 is configured as a DC/DC converter.

In FIG. 10, sw1 and sw2 indicate switching elements. Dr indicates a control circuit that controls the switching operation of the switching elements sw1 and sw2 and various protective function operations or the like. Further, R1 to R3 indicate resistors, Vref indicates an internal reference voltage circuit, ss indicates a soft start circuit, pgd indicates a power good circuit, and amp indicates an error amplifier that receives a Vref output voltage and a FB terminal voltage as inputs. In one example, one of the switching elements sw1 and sw2 corresponds to the first semiconductor element 2A, and the other corresponds to the first semiconductor element 2B. The part including the internal reference voltage circuit Vref, the soft start circuit ss, the power good circuit pgd, the error amplifier amp and the control circuit Dr corresponds to the second semiconductor element 3.

The terminal PVIN is the power input terminal of the DC/DC converter. The terminal PVIN is connected to a high potential side terminal of a DC power supply, not shown. The terminal PVIN corresponds to the lead 41 of the semiconductor device A10. The terminal PGND is the ground terminal of the DC/DC converter. The terminal PGND is connected to a low potential side terminal of the DC power supply (not shown). The terminal PGND corresponds to the lead 43 of the semiconductor device A10. The terminal SW is the output terminal of the DC/DC converter. The terminal SW corresponds to the lead 44 of the semiconductor device A10.

The terminal AVIN is an analog section power input terminal. The terminal AGND is an analog section ground terminal. The terminal EN is a device control terminal. The terminal FB is an output voltage feedback terminal. The terminal SS is a soft-start time setting terminal. The terminal COMP is a ERRAMP output terminal. The terminal PGD is a power good terminal. The terminal CTL is a control terminal for various functions. Note that the terminal MODE may be used instead of the terminal CTL. The terminal MODE is a terminal for various mode switching. Each of the terminal AVIN, the terminal AGND, the terminal EN, the terminal FB, the terminal SS, the terminal COMP, the terminal PGD, and the terminal CTL (or the terminal MODE) corresponds to a respective one of the leads 45.

The connection line between the terminal PVIN and the drain electrode of the switching element sw1 corresponds to the wires 51, and the connection line between the terminal PGND and the source electrode of the switching element sw2 corresponds to the wires 52. The connection line between the terminal SW and the source electrode of the switching element sw1 corresponds to the wire 53, and the connection line between the terminal SW and the drain electrode of the switching element sw2 corresponds to the wire 54. Connection lines for other terminals correspond to the wires 55. In the semiconductor device A10, a large current flows from the terminal PVIN to the terminal PGND, whereby a large current flows in the wires 51 to 54. In contrast, a small current flows in other terminals, so that the current flowing in each wire 55 is small.

The effects of the semiconductor device A10 are described below.

In present embodiment, each wire 51 includes a core 51A and a surface layer 51B covering the core 51A. With such a configuration of the wire 51, the core 51A is protected against corrosion by sulfur and halogen and also prevented from oxidizing. The constituent material of the surface layer 51B contains Pd. Thus, the surface layer 51B improves the bonding strength of the wires 51 to the lead 41 while preventing corrosion and oxidation of the core 51A. Further, according to the present embodiment, the constituent material of the core 51A is an alloy in which an additive metal for improving the corrosion resistance to sulfur is added to Cu, which is the base metal component. In the wire 51, therefore, even when a part of the surface layer 51B peels off to expose a part of the core 51A, corrosion of the core 51A by sulfur can be suppressed. In the present embodiment, Pt is used as the additive metal. Thus, corrosion of the core 51A by sulfur is effectively suppressed. The same holds for the wires 52 to 54.

Moreover, the wires 55 of the present embodiment do not include a portion corresponding to the surface layer 51B of the wires 51 and consist solely of a portion corresponding to the core 51A. Since only a relatively small current flows in the wires 55, corrosion by sulfur is less likely to be promoted. In the semiconductor device A10, only the wires 51 to 54, in which a large current flows and corrosion by sulfur is more likely to be promoted, have the configuration in which the core 51A is covered with the surface layer 51B. Thus, the semiconductor device A10 effectively improves resistance to corrosion by sulfur. When the constituent material of the wires 55 is Cu, to which no other metals are added, the cost for the wires 55 can be reduced as compared with the wires 51 to 54. Therefore, the semiconductor device A10 can achieve both improved resistance to corrosion by sulfur and cost reduction. Further, when the constituent material of the wires 55 is Au, the semiconductor device A10 can reduce the cost as compared with the case where the wires 51 to 54 have the same configuration as the wires 55. Moreover, since the main component of the wires 51 to 54, in which a large current flows, is Cu, loss due to resistance can be suppressed as compared with the case where Au, which has a higher electrical resistivity than Cu, is used. Therefore, the semiconductor device A10 can achieve both improved corrosion resistance to sulfur and suppression of the resistance loss and cost.

In the present embodiment, the core 51A of each wire 51 is covered with a surface layer 51B. Thee surface layer 51B has a greater bonding strength to the lead 41 than that of the core 51A. Thus, the semiconductor device A10 can suppress deterioration of the bonding condition of the wires 51 to the lead 41 (e.g., generation of cracks or peeling). The same holds for the wires 52 to 54.

In the present embodiment, each wire 51 has a main portion 511 and an end portion 512 located between the main portion 511 and the pad portion 412. The end portion 512 has the tapered section 512A of which dimension d in the z direction (see FIG. 8) decreases as proceeding away from the main portion 511. With such a configuration, the tensile stress generated in the end portion 512 in bonding the wire to the pad portion 412 is more smoothly transferred, whereby stress concentration on the end portion 512 is reduced. Further, the bond interface 412A (see FIG. 8) between the pad portion 412 and the wire 51 extends over the main portion 511 and the end portion 512 as viewed in the z direction. With such a configuration, the load due to the bonding of the wire 51 to the pad portion 412 is distributed among the end portion 512 and the main portion 511, whereby stress concentration on the end portion 512 is reduced more effectively. The same holds for the wires 52 to 54.

In the present embodiment, the sulfur content in the resin member 6 is 5 ppm or more and 50 ppm or less by mass. Since the wires 52 to 54 are highly resistant to corrosion by sulfur as noted above, the resin member 6 can contain a certain amount of sulfur. Thus, the resin member 6 can have improved adhesion to the conductive support member 4 while suppressing corrosion of the wires 52 to 54 due to a sulfur component.

Although the present embodiment describes the case where the wires 55 do not include a portion corresponding to the surface layer 51B of the wires 51 and consist solely of a portion corresponding to the core 51A, the present disclosure is not limited to this. For example, each wire 55 may have a configuration in which a core made of Cu, to which no other metals are added, is covered with a surface layer similar to the surface layer 51B of the wires 51. In such a case, the bonding strength of the wires 55 to the lead 45 is improved.

Although the present embodiment describes the case where the semiconductor device A10 includes, as the connecting members 5, wires 51 to 54 that are bonding wires, the present disclosure is not limited to this. The semiconductor device A10 may include, as the connecting member 5, bonding ribbons having the same configuration as the wires 51 to 54 (i.e., including the core 51A and the surface layer 51B covering the core 51A) and wider than the wires. The connecting members are not limited to these.

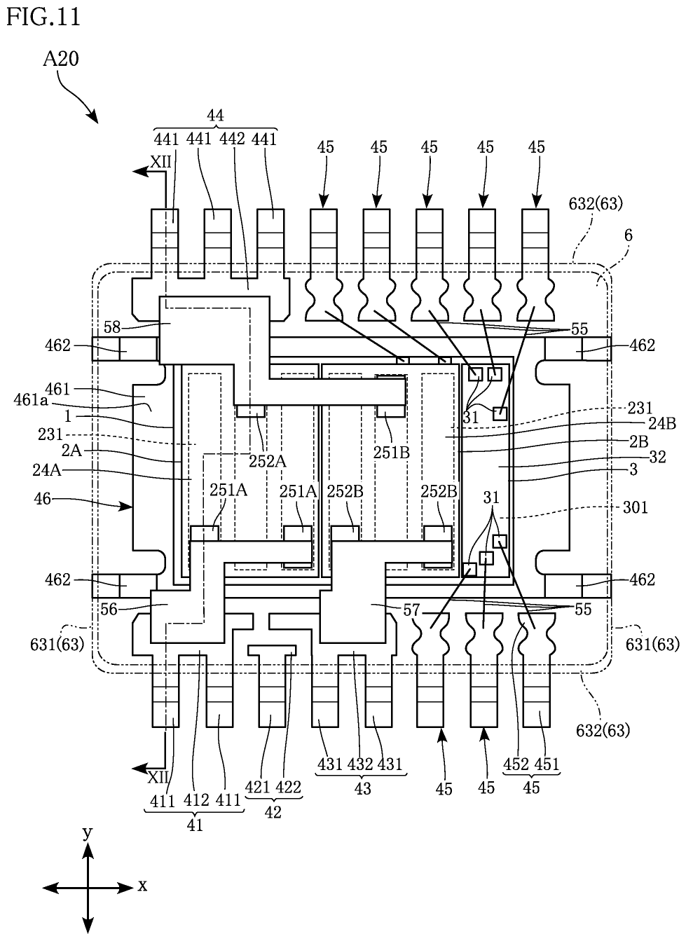

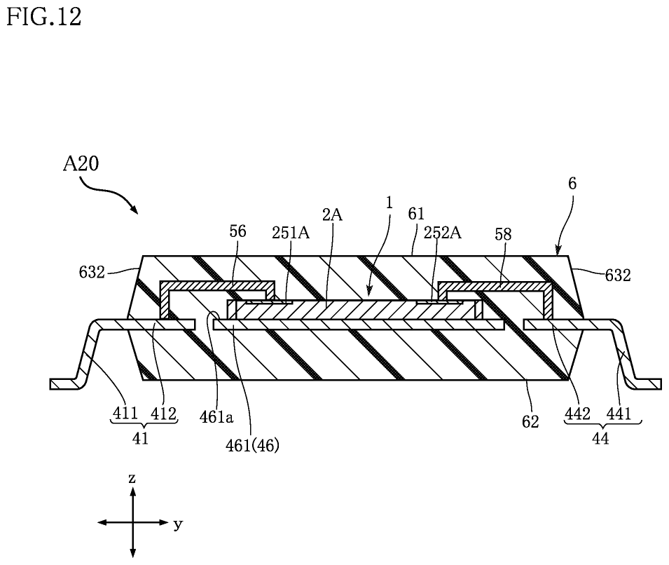

FIGS. 11 to 17 show other embodiments of the present disclosure. In these figures, the elements that are identical or similar to those of the embodiment described above are denoted by the same reference signs, and the descriptions thereof are omitted.

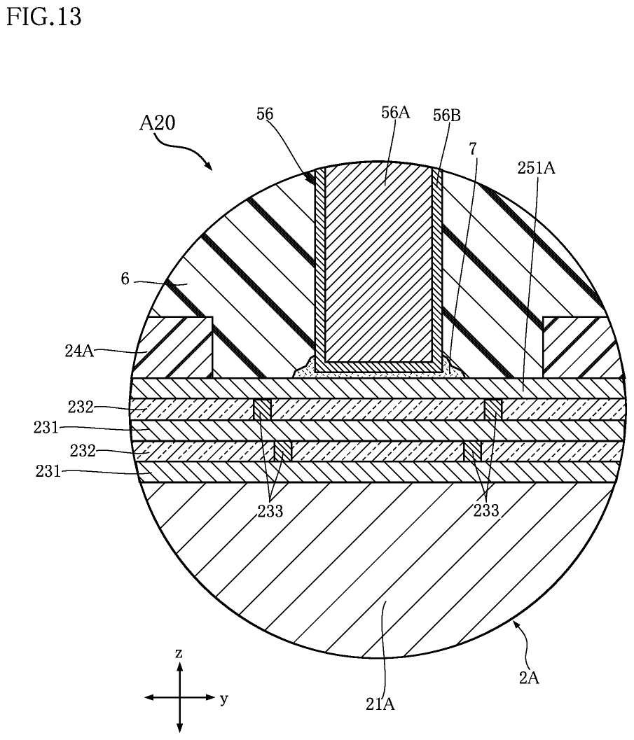

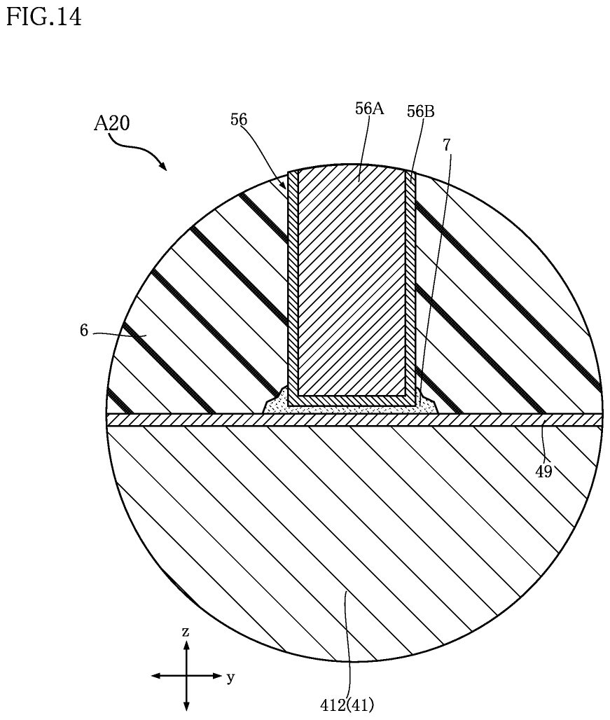

FIGS. 11 to 14 show a semiconductor device A20 according to a second embodiment of the present disclosure. FIG. 11 is a plan view of the semiconductor device A20, which corresponds to FIG. 2. For the convenience of understanding, FIG. 11 shows the resin member 6 as transparent and indicates the outlines of the resin member 6 by imaginary lines (double dashed lines). FIG. 12 is a sectional view taken along line XII-XII in FIG. 11. FIG. 13 is an enlarged view of a part of FIG. 12. FIG. 14 is an enlarged view of a part of FIG. 12. The semiconductor device A20 of the present embodiment differs from the semiconductor device A10 of the first embodiment in that it includes connection leads 56 to 58 instead of the wires 51 to 54. The configuration and operation of other parts of the present embodiment are the same as the first embodiment.

The semiconductor device A20 of the present embodiment includes connection leads 56 to 58 instead of the wires 51 to 54. The connection leads 56 to 58 electrically connect the first semiconductor elements 2A and 2B and the leads 41, 43 and 44 to each other. The connection leads 56 to 58 are plate-shaped conductors and are formed by bending a metal plate. The shape and thickness of the connection leads 56 to 58 are not limited.

As shown in FIGS. 11 and 12, the connection lead 56 electrically connects each electrode pad 251A of the first semiconductor element 2A and the pad portion 412 of the lead 41 to each other. The connection lead 56 is bonded to each electrode pad 251A via a bonding material 7 such as solder as shown in FIG. 13 and bonded to the pad portion 412 via a bonding material 7 as shown in FIG. 14. The connection lead 56 includes a main body 56A and a surface layer 56B covering the main body 56A.

The constituent material of the main body 56A is an alloy in which Pt as an additive metal is added to Cu, which is the base metal component. This alloy, in which Pt is added to Cu to improve corrosion resistance to sulfur, has a higher corrosion resistance to sulfur than that of Cu. The alloy may contain other additive metals in addition to Pt. Pt has the highest proportion among the additive metals in the alloy, and its content is, without limitation, about 50 ppm or more and 300 ppm or less by mass. The additive metal for improving corrosion resistance to sulfur is not limited to Pt and may be other metal, and preferably, is a metal with an atomic number greater than that of Cu. The base metal component of the constituent material of the main body 56A is not limited to Cu and may be other metals. In such a case as well, the constituent material of the main body 56A is an alloy in which an additive metal for improving the corrosion resistance to sulfur is added to the base metal component.

The constituent material of the surface layer 56B contains, for example, Pd. The surface layer 56B is provided to protect the main body 56A from corrosion by sulfur and halogen and prevent oxidation of the main body 56A. The constituent material of the surface layer 56B is not limited to Pd, and may be any metal having the above-described functions. The surface layer 56B may be formed on the surface of the main body 56A by plating, for example. The method for forming the connection lead 56 is not limited.

As shown in FIG. 11, the connection lead 57 electrically connects each electrode pad 252B of the first semiconductor element 2B and the pad portion 432 of the lead 43 to each other. As shown in FIGS. 11 and 12, the connection lead 58 electrically connects the electrode pad 252A of the first semiconductor element 2A and the electrode pad 251B of the first semiconductor element 2B to the pad portion 442 of the lead 44. The configuration of the connection leads 57 and 58 are the same as the connection lead 56.

In the present embodiment, the connection lead 56 includes the main body 56A and the surface layer 56B covering the main body 56A. With such a configuration of the connection lead 56, the main body 56A is protected against corrosion by sulfur and halogen and also prevented from oxidizing. The constituent material of the surface layer 56B contains Pd. The surface layer 56B can therefore prevent corrosion and oxidation of the main body 56A. Further, according to the present embodiment, the constituent material of the main body 56A is an alloy in which an additive metal for improving the corrosion resistance to sulfur is added to Cu, which is the base metal component. In the connection lead 56, therefore, even when a part of the surface layer 56B peels off to expose a part of the main body 56A, corrosion of the main body 56A by sulfur can be suppressed. In the present embodiment, Pt is used as the additive metal. Thus, corrosion of the main body 56A by sulfur is effectively suppressed. The same holds for the connection leads 57 and 58.

In the present embodiment again, the wires 55 do not include a portion corresponding to the surface layer 51B of the wires 51 and consist solely of a portion corresponding to the core 51A. Since only a relatively small current flows in the wires 55, corrosion by sulfur is less likely to be promoted. The semiconductor device A20 employs connection leads 56 to 58 only for the connecting members in which a large current flows and corrosion by sulfur is more likely to be promoted. Thus, the semiconductor device A20 effectively improves resistance to corrosion by sulfur. The semiconductor device A20 has a configuration in common with the semiconductor device A10, thereby achieving the same effect as the semiconductor device A10.

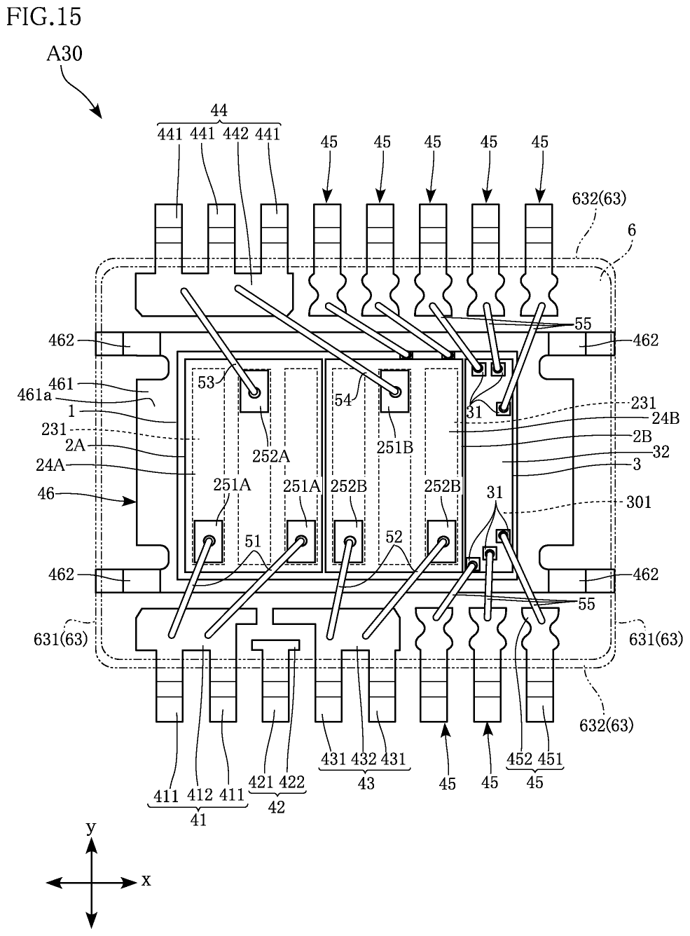

FIG. 15 shows a semiconductor device A30 according to a third embodiment of the present disclosure. FIG. 15 is a plan view of the semiconductor device A30, which corresponds to FIG. 2. For the convenience of understanding, FIG. 15 shows the resin member 6 as transparent and indicates the outlines of the resin member 6 by imaginary lines (double dashed lines). The semiconductor device A30 of the present embodiment differs from the semiconductor device A10 of the first embodiment in configuration of each wire 55. The configuration and operation of other parts of the present embodiment are the same as the first embodiment. Note that various parts of the first and the second embodiments described above may be selectively used in an any appropriate combination.

The wires 55 of the present embodiment have the same configuration as the wires 51. That is, all connecting members 5 (the wires 51 to 55) of the semiconductor device A30 include the core 51A and the surface layer 51B covering the core 51A.

In the present embodiment, each of the wires 51 to 55 includes a core 51A and a surface layer 51B covering the core 51A. With such a configuration of the wires 51 to 55, the cores 51A are protected against corrosion by sulfur and halogen and also prevented from oxidizing. The constituent material of the surface layer 51B contains Pd. Thus, the surface layer 51B improves the bonding strength of the wires 51 to 55 to the conductive support member 4 while preventing corrosion and oxidation of the core 51A. Further, according to the present embodiment, the constituent material of the core 51A is an alloy in which an additive metal for improving the corrosion resistance to sulfur is added to Cu, which is the base metal component. In the wires 51 to 55, therefore, even when a part of the surface layer 51B peels off to expose a part of the core 51A, corrosion of the core 51A by sulfur can be suppressed. In the present embodiment, Pt is used as the additive metal. Thus, corrosion of the core 51A by sulfur is effectively suppressed. The semiconductor device A30 has a configuration in common with the semiconductor device A10, thereby achieving the same effect as the semiconductor device A10. According to the present embodiment, the same wire material can be used for the wires 51 to 55. Therefore, it is not necessary to change the wire material or the bonding method depending on the wire to be formed, so that the manufacturing process can be simplified.

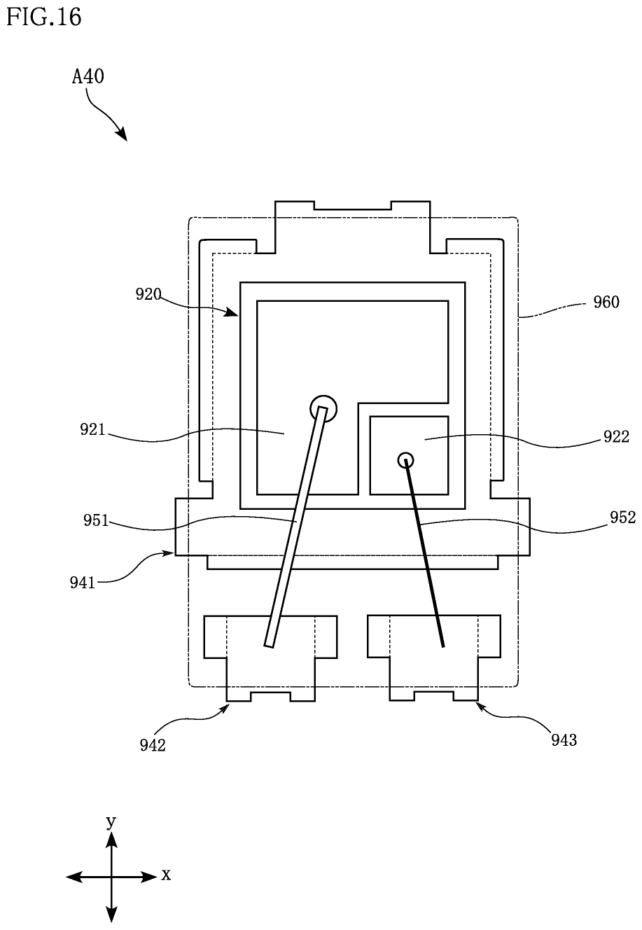

FIG. 16 shows a semiconductor device A40 according to a fourth embodiment of the present disclosure. FIG. 16 is a plan view of the semiconductor device A40, which corresponds to FIG. 2. For the convenience of understanding, FIG. 16 shows the resin member 960 as transparent and indicates the outlines of the resin member 960 by imaginary lines (double dashed lines). The semiconductor device A40 of the present embodiment differs from the semiconductor device A10 of the first embodiment in that it includes a semiconductor element 920 instead of the electronic component 1. The configuration and operation of other parts of the present embodiment are the same as the first embodiment. Note that various parts of the first through the third embodiments described above may be selectively used in an any appropriate combination.

The semiconductor device A40 according to the present embodiment may have a package called DFN (Dual Flatpack No-leaded), for example. The package type of the semiconductor device A40 is not limited. The semiconductor device A40 includes the semiconductor element 920 instead of the electronic component 1. The semiconductor device A40 also includes leads 941 to 943 as the conductive support member 4, wires 951 and 952 as the connecting members 5, and a resin member 960.

The lead 941 is disposed at the end on one side in the y direction (the upper side in FIG. 16) of the semiconductor device A40 and extends throughout the entirety of the device in the x direction. The lead 942 is disposed at the corner on the other side in the y direction (the lower side in FIG. 16) and on one side in the x direction (the left side in FIG. 16). The lead 943 is disposed at the corner on said other side in the y direction and on the other side in the x direction (the right side in FIG. 16). The lead 942 and the lead 943 are spaced apart from the lead 941 in the y direction and spaced apart from each other in the x direction. The lead 941 supports the semiconductor element 920. Each of the leads 941 to 943 is electrically connected to the semiconductor element 920.

The semiconductor element 920 is, for example, a MOSFET. The semiconductor element 920 may be other transistors such as an IGBT. The semiconductor element 920 has a source electrode 921 and a gate electrode 922 disposed on its obverse surface and a drain electrode disposed on its reverse surface. The drain electrode of the semiconductor element 920 is electrically connected to the lead 941 via a bonding material. Thus, the lead 941 functions as a drain terminal. The source electrode 921 of the semiconductor element 920 is electrically connected to the lead 942 via a wire 951. Thus, the lead 942 functions as a source terminal. The gate electrode 922 of the semiconductor element 920 is electrically connected to the lead 943 via a wire 952. Thus, the lead 943 functions as a gate terminal.

The wire 951 electrically connects the source electrode 921 of the semiconductor element 920 and the lead 942 to each other. The wire 951 is bonded to the source electrode 921 at one end and bonded to the lead 942 at the other end. The wire 951 has the same configuration as the wires 51 of the first embodiment and includes a core 51A and a surface layer 51B covering the core 51A. The wire 952 electrically connects the gate electrode 922 of the semiconductor element 920 and the lead 943 to each other. The wire 952 is bonded to the gate electrode 922 at one end and bonded to the lead 943 at the other end. The wire 952 has the same configuration as the wires 55 of the first embodiment. Since a relatively large current flows in the source electrode 921, a relatively large current flows in the wire 951 as well. A relatively small current flows in the gate electrode 922 as compared with the current flowing in the source electrode 921. Therefore, the current flowing in the wire 952 is smaller than the current flowing in the wire 951. In the present embodiment, only the wire 951, in which a large current flows and corrosion by sulfur is more likely to promoted, has the configuration in which the core 51A is covered with the surface layer 51B. The wire 952, in which a relatively small current flows, does not include the surface layer.

In the present embodiment, the wire 951 includes a core 51A and a surface layer 51B covering the core 51A. With such a configuration of the wire 951, the core 51A is protected against corrosion by sulfur and halogen and also prevented from oxidizing. The constituent material of the surface layer 51B contains Pd. Thus, the surface layer 51B improves the bonding strength of the wire 951 to the lead 942 while preventing corrosion and oxidation of the core 51A. Further, according to the present embodiment, the constituent material of the core 51A is an alloy in which an additive metal for improving the corrosion resistance to sulfur is added to Cu, which is the base metal component. In the wire 951, therefore, even when a part of the surface layer 51B peels off to expose a part of the core 51A, corrosion of the core 51A by sulfur can be suppressed. In the present embodiment, Pt is used as the additive metal. Thus, corrosion of the core 51A by sulfur is effectively suppressed.

In the present embodiment again, the wire 952 does not include a portion corresponding to the surface layer 51B of the wire 951 and consists solely of a portion corresponding to the core 51A. Since only a relatively small current flows in the wire 952, corrosion by sulfur is less likely to be promoted. In the semiconductor device A40, only the wire 951, in which a large current flows and corrosion by sulfur is more likely to be promoted, has the configuration in which the core 51A is covered with the surface layer 51B. Thus, the semiconductor device A40 effectively improves resistance to corrosion by sulfur. When the constituent material of the wire 952 is Cu, to which no other metals are added, the cost for the wire 952 can be reduced as compared with the wire 951. Therefore, the semiconductor device A40 can achieve both improved resistance to corrosion by sulfur and cost reduction. Further, when the constituent material of the wire 952 is Au, the semiconductor device A40 can reduce the cost as compared with the case where the wire 951 has the same configuration as the wire 952. Moreover, since the main component of the wire 951, in which a large current flows, is Cu, loss due to resistance can be suppressed as compared with the case where Au, which has a higher electrical resistivity than Cu, is used. Therefore, the semiconductor device A40 can achieve both improved corrosion resistance to sulfur and suppression of the resistance loss and cost. The semiconductor device A40 has a configuration in common with the semiconductor device A10, thereby achieving the same effect as the semiconductor device A10.

Although the present embodiment describes the case where the semiconductor element 920 is a transistor, the present disclosure is not limited to this. The type of the semiconductor element 920 is not limited. The number, shape, and arrangement of the conductive support member 4 are not limited, nor is the number of connecting members 5.

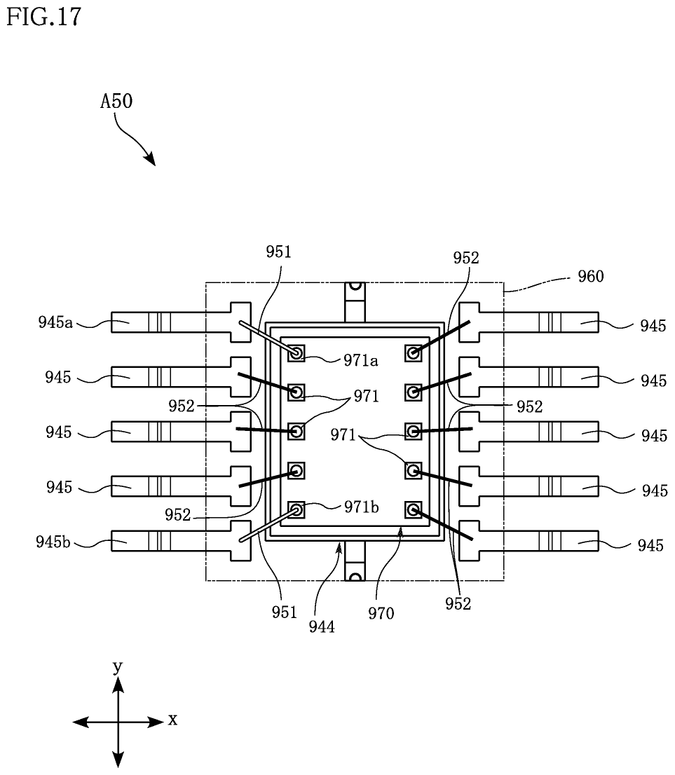

FIG. 17 shows a semiconductor device A50 according to a fifth embodiment of the present disclosure. FIG. 17 is a plan view of the semiconductor device A50, which corresponds to FIG. 2. For the convenience of understanding, FIG. 17 shows the resin member 960 as transparent and indicates the outlines of the resin member 960 by imaginary lines (double dashed lines). The semiconductor device A50 of the present embodiment differs from the semiconductor device A10 of the first embodiment in that it includes a semiconductor element 970 instead of the electronic component 1. The configuration and operation of other parts of the present embodiment are the same as the first embodiment. Note that various parts of the first through the fourth embodiments described above may be selectively used in an any appropriate combination.

The semiconductor device A50 of the present embodiment includes the semiconductor element 970 instead of the electronic component 1. The semiconductor device A50 also includes a lead 944 and a plurality of leads 945 as the conductive support member 4, wires 951 and 952 as the connecting members 5, and a resin member 960.

The lead 944 is disposed at the center of the semiconductor device A50 in the x direction and extends throughout the entirety of the device in the y direction. The plurality of leads 945 are arranged on both sides of the lead 944 in the x direction, five on each side, at equal intervals in the y direction. The leads 945 are spaced apart from the lead 944 and spaced apart from each other. The lead 944 supports the semiconductor element 970. Each lead 945 is electrically connected to the semiconductor element 970. In the present embodiment, the leads 945 includes a lead 945a and a lead 945b. The lead 945a is disposed at the top of the left side in FIG. 17, and the lead 945b is disposed at the bottom of the left side in FIG. 17.

The semiconductor element 970 is, for example, an LSI (Large Scale Integration). The semiconductor element 970 may be other electronic components. The semiconductor element 970 is bonded to the lead 944 via a bonding material. The semiconductor element 970 has a plurality of electrode pads 971 disposed on its obverse surface. The plurality of electrode pads 971 include an electrode pad 971a and an electrode pad 971b. The electrode pad 971a is a power supply electrode. The electrode pad 971b is a ground electrode. In the present embodiment, the electrode pad 971a is disposed at the top of the left side on the obverse surface in FIG. 17, and the electrode pad 971b is disposed at the bottom of the left side on the obverse surface in FIG. 17. The position of each electrode pad 971 is not limited. The electrode pads 971 other than the electrode pads 971a and 971b are connected to different leads 945 via wires 952. The electrode pad 971a is connected to the lead 945a via a wire 951. Thus, the lead 945a functions as a power supply terminal. The electrode pad 971b is connected to the lead 945b via a wire 951. Thus, the lead 945b functions as a ground terminal.

A wire 951 electrically connects the electrode pad 971a of the semiconductor element 970 and the lead 945a to each other. The wire 951 is bonded to the electrode pad 971a at one end and bonded to the lead 945a at the other end. Another wire 951 electrically connects the electrode pad 971b of the semiconductor element 970 and the lead 945b to each other. The wire 951 is bonded to the electrode pad 971b at one end and bonded to the lead 945b at the other end. Each of these wires 951 has the same configuration as the wires 51 of the first embodiment and includes a core 51A and a surface layer 51B covering the core 51A. The wires 952 electrically connect the electrode pads 971 other than the electrode pads 971a and 971b and the leads 945 other than the leads 945a and 945b. Each wire 952 is bonded to an electrode pad 971 at one end and bonded to a lead 945 at the other end. The wires 952 have the same configuration as the wires 55 of the first embodiment. Since a relatively large current flows in the electrode pads 971a and 971b, a relatively large current flows in the wires 951 as well. On the other hand, a relatively small current flows in the electrode pads 971 other than the electrode pads 971a and 971b, so that a relatively small current flows in the wires 952. In the present embodiment, only the wires 951, in which a relatively large current flows and corrosion by sulfur is more likely to be promoted, have the configuration in which the core 51A is covered with the surface layer 51B. The wires 952, in which a relatively small current flows, do not include the surface layer.

In the present embodiment, each wire 951 includes a core 51A and a surface layer 51B covering the core 51A. With such a configuration of the wires 951, the core 51A is protected against corrosion by sulfur and halogen and also prevented from oxidizing. The constituent material of the surface layer 51B contains Pd. Thus, the surface layer 51B improves the bonding strength of the wires 951 to the leads 945a and 945b while preventing corrosion and oxidation of the core 51A. Further, according to the present embodiment, the constituent material of the core 51A is an alloy in which an additive metal for improving the corrosion resistance to sulfur is added to Cu, which is the base metal component. In the wires 951, therefore, even when a part of the surface layer 51B peels off to expose a part of the core 51A, corrosion of the core 51A by sulfur can be suppressed. In the present embodiment, Pt is used as the additive metal. Thus, corrosion of the core 51A by sulfur is effectively suppressed.

In the present embodiment, the wires 952 do not include a portion corresponding to the surface layer 51B of the wires 951 and consist solely of a portion corresponding to the core 51A. Since only a relatively small current flows in the wires 952, corrosion by sulfur is less likely to be promoted. In the semiconductor device A50, only the wires 951, in which a large current flows and corrosion by sulfur is more likely to be promoted, has the configuration in which the core 51A is covered with the surface layer 51B. Thus, the semiconductor device A50 effectively improves resistance to corrosion by sulfur. When the constituent material of the wires 952 is Cu, to which no other metals are added, the cost for the wires 952 can be reduced as compared with the wires 951. Therefore, the semiconductor device A50 can achieve both improved resistance to corrosion by sulfur and cost reduction. Further, when the constituent material of the wires 952 is Au, the semiconductor device A50 can reduce the cost as compared with the case where the wires 951 has the same configuration as the wires 952. Moreover, since the main component of the wires 951, in which a large current flows, is Cu, loss due to resistance can be suppressed as compared with the case where Au, which has a higher electrical resistivity than Cu, is used. Therefore, the semiconductor device A50 can achieve both improved resistance to corrosion by sulfur and suppression of the resistance loss and cost. The semiconductor device A50 has a configuration in common with the semiconductor device A10, thereby achieving the same effect as the semiconductor device A10.

Although the present embodiment describes the case where the semiconductor element 970 is an LSI, the present disclosure is not limited to this. The type of the semiconductor element 970 is not limited. The number, shape, and arrangement of the conductive support member 4 are not limited, nor is the number of connecting members 5.

The semiconductor device according to the present disclosure is not limited to the above-described embodiments. Various modifications in design may be made freely in the specific structure of each part of the semiconductor device according to the present disclosure. The present disclosure includes embodiments described in the following clauses.
Clause 1.
A semiconductor device comprising:
a semiconductor element (2A);
a first lead (41) electrically connected to the semiconductor element; and
a connecting member (51) connected to the semiconductor element and the first lead, wherein
the connecting member includes a core (51A) containing a first material and a surface layer (51B), the surface layer covering the core and containing a first metal (Pd),
the first material includes an alloy in which at least a third metal (Pt) is added to a second metal (Cu) and has a higher corrosion resistance than the second metal, and
the third metal has a highest proportion among the metals added and has an atomic number greater than the second metal.
Clause 2.
The semiconductor device according to clause 1, wherein the second metal is Cu.
Clause 3.
The semiconductor device according to clause 1 or 2, wherein the third metal is Pt.
Clause 4.
The semiconductor device according to any one of clauses 1 to 3, wherein the first metal has a greater bonding strength to the first lead than the first material.
Clause 5.
The semiconductor device according to any one of clauses 1 to 4, wherein the first metal is Pd.
Clause 6.
The semiconductor device according to any one of clauses 1 to 5, wherein the connecting member is a wire.
Clause 7. (the first through the third embodiments, FIG. 2)
The semiconductor device according to any one of clauses 1 to 6, further comprising:
a second semiconductor element (3);
a second lead (45) electrically connected to the second semiconductor element; and
a second connecting member (55) connected to the second semiconductor element and the second lead and configured such that a current flowing therein is smaller than a current flowing in the connecting member,
wherein the second connecting member consists solely of a second core containing a second material (Cu).
Clause 8.
The semiconductor device according to clause 7, wherein the semiconductor element is a transistor, and
the second semiconductor element is a driver IC that drives and controls the transistor.
Clause 9. (the fourth embodiment, FIG. 16)
The semiconductor device according to any one of clauses 1 to 6, further comprising:
a second lead (943) electrically connected to the semiconductor element (920); and
a second connecting member (952) connected to the semiconductor element and the second lead and configured such that a current flowing therein is smaller than a current flowing in the connecting member,
wherein the second connecting member consists solely of a second core containing a second material.
Clause 10.
The semiconductor device according to clause 9, wherein the semiconductor element is a transistor.
Clause 11.
The semiconductor device according to any one of clauses 7 to 10, wherein the second material consists solely of the second metal (Cu) to which no other metals are added.
Clause 12.
The semiconductor device according to any one of clauses 7 to 10, wherein the second material contains a fourth metal (Au) having a higher electrical resistivity than the second metal (Cu).
Clause 13.
The semiconductor device according to clause 12, wherein the fourth metal is Au.
Clause 14.
The semiconductor device according to any one of clauses 1 to 13, further comprising a resin member (6) covering the connecting member, and
the resin member has a sulfur content of 5 ppm or more.

### REFERENCE NUMERALS

A10, A20, A30, A40: Semiconductor device
1: Electronic component
2A, 2B: First semiconductor element
21A, 21B: Semiconductor substrate
211A, 211B: Substrate obverse surface
212A, 212B: Substrate reverse surface
220A, 220B: Active region 221A, 221B: Semiconductor region
222A, 222B: Semiconductor region
223A, 223B: Semiconductor region
23A, 23B: Wiring layer 231: Conductive layer
232: Insulating layer
233: Via 24A, 24B: Protective film
251A, 251B, 252A, 252B: Electrode pad
3: Second semiconductor element 301: Element obverse surface
31: Electrode pad
32: Protective film 4: Conductive support member 41: Lead
411: Terminal portion 412: Pad portion 412A: Bond interface
42: Lead 421: Terminal portion 422: Pad portion
43: Lead 431: Terminal portion 432: Pad portion
44: Lead 441: Terminal portion 442: Pad portion
45: Lead 451: Terminal portion 452: Pad portion
46: Die pad 461: Pad portion
461a: Die pad obverse surface 462: Extension portion
462a: End surface
49: Metal layer 5: Connecting member 51 to 55: Wire
51A: Core 51B: Surface layer 511: Main portion
512: End portion 512A: Tapered section 512B: Tip
56 to 58: Connection lead 56A: Main body
56B: Surface layer
6: Resin member 61: Resin obverse surface
62: Resin reverse surface
63, 631, 632: Resin side surfaces 7: Bonding material
920,970: Semiconductor element 921: Source electrode
922: Gate electrode 971, 971a, 971b: Electrode pad
941 to 945, 945a, 945b: Lead
951, 952: Wire 960: Resin member

1. A semiconductor device comprising:
a semiconductor element;
a first lead electrically connected to the semiconductor element; and
a connecting member connected to the semiconductor element and the first lead, wherein
the connecting member includes a core containing a first material and a surface layer, the surface layer covering the core and containing a first metal,
the first material includes an alloy in which at least a third metal is added to a second metal and has a higher corrosion resistance than the second metal, and
the third metal has a highest proportion among the metals added and has an atomic number greater than the second metal.

2. The semiconductor device according to claim 1, wherein the second metal is Cu.

3. The semiconductor device according to claim 1, wherein the third metal is Pt.

4. The semiconductor device according to claim 1, wherein the first metal has a greater bonding strength to the first lead than the first material.

5. The semiconductor device according to claim 1, wherein the first metal is Pd.

6. The semiconductor device according to claim 1, wherein the connecting member is a wire.

7. The semiconductor device according to claim 1, further comprising:
a second semiconductor element;
a second lead electrically connected to the second semiconductor element; and
a second connecting member connected to the second semiconductor element and the second lead and configured such that a current flowing therein is smaller than a current flowing in the connecting member,
wherein the second connecting member consists solely of a second core containing a second material.

8. The semiconductor device according to claim 7, wherein the semiconductor element is a transistor, and
the second semiconductor element is a driver IC that drives and controls the transistor.

9. The semiconductor device according to claim 1, further comprising:
a second lead electrically connected to the semiconductor element; and
a second connecting member connected to the semiconductor element and the second lead and configured such that a current flowing therein is smaller than a current flowing in the connecting member,
wherein the second connecting member consists solely of a second core containing a second material.

10. The semiconductor device according to claim 9, wherein the semiconductor element is a transistor.

11. The semiconductor device according to claim 7, wherein the second material consists solely of the second metal to which no other metals are added.

12. The semiconductor device according to claim 7, wherein the second material contains a fourth metal having a higher electrical resistivity than the second metal.

13. The semiconductor device according to claim 12, wherein the fourth metal is Au.

14. The semiconductor device according to claim 1, further comprising a resin member covering the connecting member, and
the resin member has a sulfur content of 5 ppm or more.
